(19) United States
(12) Patent Application Publication
(10) Pub. No.: US 2004/0185674 A1
(43) Pub. Date: Sep. 23, 2004

(54) Nitrogen-free hard mask over low K dielectric

(75) Inventors: Hichem M'Saad, Santa Clara, CA (US); Sang Ahn, San Mateo, CA (US)

Correspondence Address: Patent Counsel, M/S 2061, APPLIED MATERIALS, INC., Legal Affairs Department, P.O. Box 450A, Santa Clara, CA, 95052, US

(73) Assignee: Applied Materials, Inc., Santa Clara, CA

(21) Appl. No.: 10/391,143

(22) Filed: Mar. 17, 2003

(51) Int. Cl. H01L 21/31

(52) U.S. Cl. 438/761; 438/72; 438/787; 438/780

(57) ABSTRACT

A layer of nitrogen-free oxide material is formed as a hard mask to minimize resist poisoning during patterning of low K dielectric layers. In one embodiment, the oxide hard mask material has the formula Si_{w}Oₓ, where w and x represent the atomic percentage of silicon and oxygen, respectively, in the material and where w is about 1 and x is about 2, and the density of nitrogen in the silicon oxide material of the hard mask is less than or equal to about 1×10¹⁶ atoms/cm³.

### BACKGROUND OF THE INVENTION

The evolution of integrated circuits has seen a continuing decrease in the size of features that are fabricated in and on semiconductor wafers. Photolithographic processes are one of many fabrication steps critical in forming such small feature size structures. Conventional photolithographic techniques include forming a layer of energy sensitive resist over a material stack formed on a substrate. An image of a pattern is introduced into the energy sensitive resist layer by directing radiation through an appropriately patterned photomask. The substrate is then exposed to a chemical etchant to transfer the pattern introduced into the energy sensitive resist layer into one or more layers of the material stack. The chemical etchant is selected to have a greater etch selectivity for the material layers of the stack than for the energy sensitive resist. That is, the chemical etchant etches the one or more layers of the material stack at a faster rate than it etches the energy sensitive resist. The faster etch rate for the one or more material layers of the stack typically prevents the energy sensitive resist material from being consumed prior to completion of the pattern transfer.

Photolithographic processes used in the manufacture of many modern integrated circuits (e.g., integrated circuits having minimum features sizes of about 0.35 microns or less) employ deep ultraviolet (DUV) imaging wavelengths (e.g., wavelengths of 248 nm or 193 nm) to generate the resist patterns. The DUV imaging wavelengths improve resist pattern resolution because diffraction effects are reduced at these shorter wavelengths.

Low K dielectric layers are one type of material which may be patterned by photolithographic processes during the fabrication of semiconductor devices. Such low K dielectric materials are characterized by their low dielectric constant (K), typically less than 3.5, which is effective to provide insulation between conductive portions of the circuit, and thereby reduce problems associated with cross-talk and noise. Examples of such low K dielectric materials include Black Diamond™ and BloK™ layers available through Applied Materials, assignee of the present invention.

One issue arising with patterning photoresist directly over low K dielectric materials is that the low K dielectric materials may contain amines (NH₂ groups). The exposure of photoresists that are typically used with deep UV radiation generally creates an acidic reaction in the photoresist. The resulting acid compounds react with the developer to create a mask. However, since amines present in the low K dielectric layer are basic, they may neutralize the acids generated by the exposure of the photoresist and thereby limit the development of the photoresist. This problem, which is often referred to as “resist poisoning” or “footing”, may result in small foot-like portions of resist that are left undeveloped near the interface between the low K dielectric and resist, and which may ultimately interfere with the patterning of features underneath the photoresist.

FIGS. 1A-1E illustrate an exemplary conventional etch sequence that may be used in the formation of integrated circuits having signal lines formed by interconnect metallization. In FIG. 1A a low K dielectric layer 12 containing nitrogen is formed over a substrate 10. Substrate 10 may be any suitable substrate material upon which semiconductor devices are formed, such as a silicon substrate, a germanium substrate, a silicon-germanium substrate and the like. Substrate 10 may also include a plurality of layers already formed over the base substrate material, for example a barrier layer or an interconnect metallization layer.

As shown in FIG. 1B, undeveloped photoresist layer 18 may then be formed over low K dielectric 12. In FIG. 1C, photoresist layer 18 is exposed to radiation 17 transmitted through reticle 19. Specifically, reticle 19 includes opaque portions 19a which block the incident radiation 17, and also includes transparent portions 19b which transmit the incident radiation 17. Due to the presence of reticle 19, selective regions of photoresist layer 18 are exposed to radiation for patterning according to a via pattern. Specifically, regions 18a of photoresist layer 18 are exposed to radiation, while regions 18b remain unaffected. As a result of this radiation exposure, photoresist in regions 18a may experience a change, for example the generation of acidic species.

As shown in FIG. 1D, developer solution is next applied to the processed substrate. Photoresist material in regions 18a exposed to the radiation is soluble in the developer solution. Photoresist material in regions 18b not exposed to the radiation is insoluble in the developer solution. FIG. 1D thus shows removal of photoresist 18 in exposed regions 18a, but not in unexposed regions 18b, to form via pattern 20.

The effectiveness of the photoresist development step shown in FIG. 1D is dependent upon concentration of acids produced in the resist as a result of exposure to the radiation. Prior to development of the resist, however, amines in low K dielectric 12 may diffuse upward into photoresist layer 18. This amine migration may neutralize some of the acid generated in exposed regions 18a, thereby interfering with complete development of the photoresist layer. As a result of such photoresist poisoning, FIG. 1D shows that some unwanted, undeveloped photoresist portions 18c may remain along the interface with low K dielectric layer 12.

In FIG. 1E the via pattern 20 is transferred into low K dielectric layer 12 to form via hole 24 using any appropriate etch sequence as is known to those of skill in the art. This etch step also removes a portion of the photoresist layer 18. In exposed regions where undeveloped photoresist remained due to resist poisoning, the extent of etching into the low K dielectric layer will be affected, and etching of the via may be incomplete or uneven due to the resist poisoning effect, as shown by low K portions 12a remaining in via hole 24.

FIG. 1F shows completion of the fabrication of the via structure. Specifically, the remaining photoresist is stripped and then a conducting metal 25 is formed over the low K dielectric layer 12, including within the via hole. This metal 25 is then removed outside of via hole 24, typically by chemical mechanical polishing (CMP), to form the metal via plug 26. However, the presence of non-etched low K dielectric 12a remaining at the bottom of the via hole can undesirably result in incomplete electrical contact being established.

Accordingly, there is a need in the art for methods for forming patterns of low K dielectric materials which avoid resist poisoning and other problems.

### BRIEF SUMMARY OF THE INVENTION

Embodiments of the invention pertain to methods of forming oxide hard masks substantially free of nitrogen overlying low-K dielectric layers. The nitrogen-free oxide hard masks in accordance with embodiments of the present invention do not harbor amines that may migrate from the low K dielectric layer into an adjacent photoresist layer. Such nitrogen-free oxide hard masks are particularly useful in photolithographic patterning processes employing chemically amplified photoresists prone to resist poisoning. Embodiments of the invention are particularly useful in patterning material using deep UV radiation of 248, 193 or 157 nm and e-beam radiation, but are also believed to be useful in other patterning processes.

According to one embodiment of the invention, a layer of nitrogen-free oxide material for use as a hard mask in photolithographic processing is provided. The oxide hard mask material exhibits nitrogen density of less than or equal to about 1×10¹⁶ atoms/cm³.

An embodiment of a method in accordance with the present invention for forming a dual damascene structure comprises the steps of patterning a first resist overlying a low K dielectric layer to reveal a first exposed region having a first width, and removing a portion of the low K dielectric layer underlying the first exposed region to form a recess. The first resist is removed, and a material is formed over the low K dielectric material and within the recess. An oxide hard mask having a nitrogen density of less than about 1×10¹⁶ atoms/cm³ is formed over the material. A second resist is patterned over the oxide hard mask to reveal a second exposed region. The oxide hard mask underlying the second exposed region is removed to form an opening having a second width over the filled recess. The second resist is removed, and the material underlying the opening is removed selective to the low K dielectric layer. The low K dielectric underlying the opening is removed to create a dual damascene hole, and a conductor material is formed within the dual damascene hole.

According to another embodiment of the present invention, a method for fabricating an integrated circuit is provided. The method comprises depositing an oxide hard mask over a substrate using a chemical vapor deposition process, forming a layer of photoresist over the oxide hard mask and then patterning the photoresist layer. The oxide hard mask exhibits a nitrogen density of less than or equal to about 1×10¹⁶ atoms/cm³.

These and other embodiments of the invention along with many of its advantages and features are described in more detail in conjunction with the text below and attached figures.

### BRIEF DESCRIPTION OF THE DRAWINGS

FIGS. 1A-1F are simplified cross-sectional views of a low K dielectric material being patterned over a substrate according to a conventional etch sequence;

FIG. 2 is a flowchart illustrating the steps associated with forming an integrated circuit according to one embodiment of the method of the present invention;

FIGS. 3A-3H are simplified cross-sectional views of a substrate being processed according to the sequence of steps set forth in FIG. 2; and

FIGS. 4A and 4B are simplified vertical, cross-sectional views of an exemplary plasma enhanced chemical vapor deposition apparatus that can be used to deposit a nitrogen-free oxide hard mask according to embodiments of the present invention.

FIGS. 5A-J are simplified cross-sectional views of a substrate being processed according to an embodiment of the present invention to form a dual damascene structure.

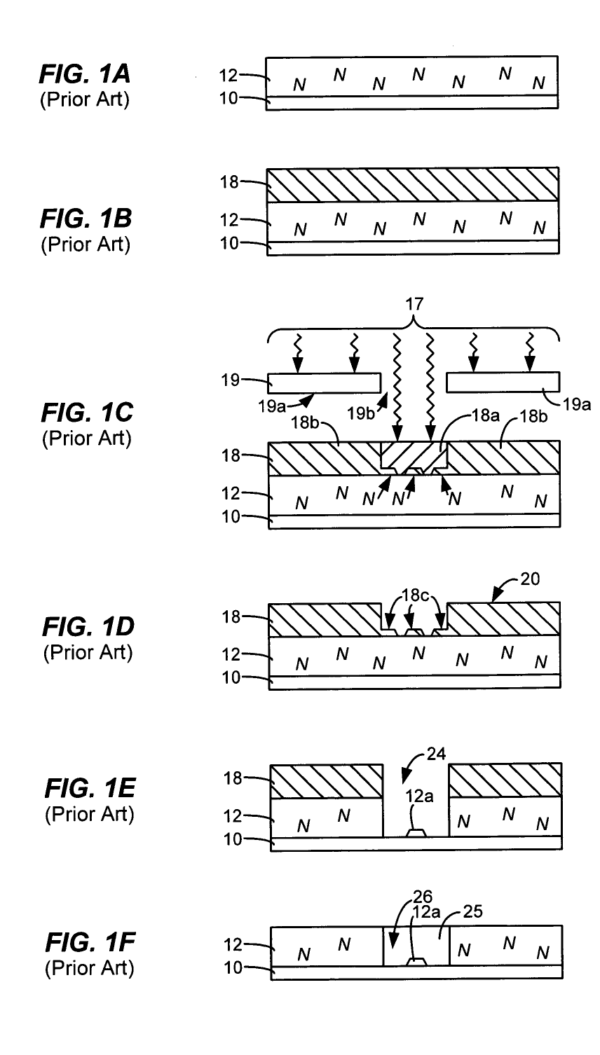

### DETAILED DESCRIPTION OF THE INVENTION

Embodiments of the invention pertain to methods of forming oxide hard masks that are substantially free of nitrogen, which overlie low K dielectric layers. Such nitrogen-free hard masks are particularly useful in photolithographic patterning processes that employ chemically amplified resists, the proper development of which depends on the catalytic effect of photo-generated acid. Hard masks formed according to embodiments of the invention incorporate minimal amounts of nitrogen, and are thus less likely to interfere with formation of acid in the resist than other hard mask materials or a bare underlying low K dielectric layer.

Hard masks according to embodiments of the invention can be deposited using chemical vapor deposition techniques and are substantially nitrogen-free films. Previously known silicon dioxide, silicon nitride and silicon oxynitride hard masks are typically deposited utilizing some nitrogen-containing gas precursor such as N₂O, and as a result generally contain between 5-20 atomic percent nitrogen. In contrast, oxide hard masks according to various embodiments of the present invention are deposited using nitrogen-free precursors, and thus generally contain significantly less than 1 atomic percent nitrogen, corresponding to a nitrogen density of less than or equal to about 1×10¹⁶ atoms/cm³.

A nitrogen-free hard mask according to embodiments of the invention can be formed by a plasma CVD reaction in a nitrogen-free ambient, including for example a nitrogen-free silicon source and a nitrogen-free oxygen source. In some embodiments, an inert gas such as helium may also added to stabilize the plasma and to control the deposition rate. In one specific embodiment, a nitrogen-free oxide hard mask is formed by forming a plasma from a gaseous mixture of monosilane (SiH₄), carbon dioxide (CO₂) and helium (He). Such a deposition process beneficially incorporates a small amount of carbon into the film, which can be varied between about 1-3 at. %, depending on deposition conditions, when CO₂ is used as the oxygen source.

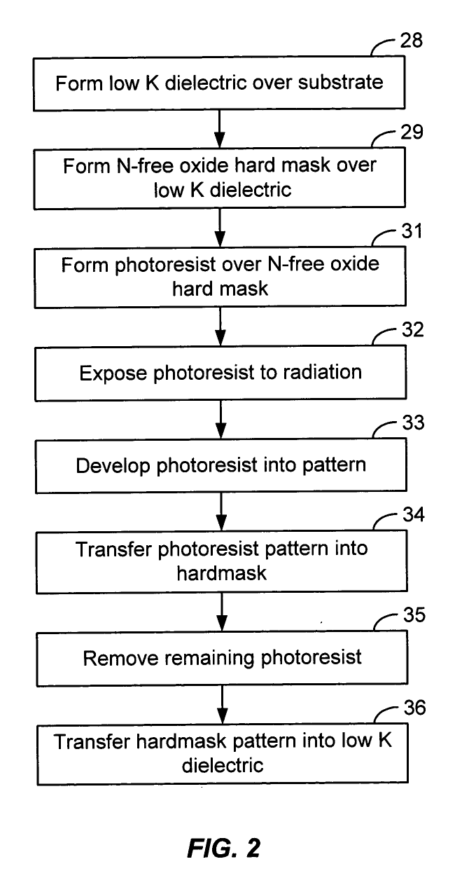

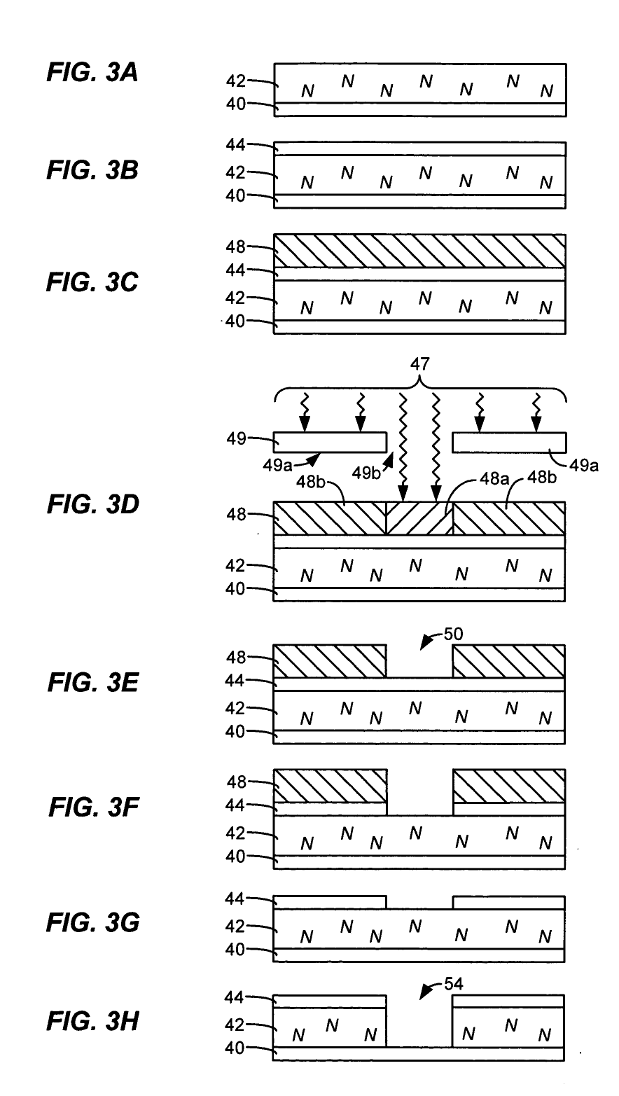

In order to better appreciate and understand the present invention, an example of its use is set forth below in the formation of a via in an interconnect structure. This example is described with respect to FIG. 2, which is a flow chart depicting the processing steps discussed in the example, and FIGS. 3A-H, which are simplified cross-sectional views of a substrate being processed according to the steps depicted in FIG. 2.

Referring to FIG. 2, this example starts with the formation of a nitrogen-containing low K dielectric layer 42 over a substrate 40 (step 28 and FIG. 3A). Substrate 40 may be any suitable substrate material upon which semiconductor devices are formed, such as a silicon substrate, a germanium substrate, a silicon-germanium substrate and the like. Substrate 40 may also include a plurality of already formed layers over the base substrate material, for example a nitrogen-free oxide hard mask material in accordance with an embodiment of the present invention. Low K dielectric layer 42 may comprise a single layer of insulative material, or may be a stack of layers. In one specific embodiment layer, low K dielectric 42 includes a carbon-doped silicon oxide layer such as Black Diamond™ available from Applied Materials, Inc. of Santa Clara, Calif., assignee of the present invention, deposited over a silicon carbide layer, such as a BloK™ layer also available from Applied Materials, Inc. The Black Diamond™ layer is the primary dielectric layer in which both a trench and via structure are formed. The BloK™ layer is a bottom etch stop layer.

Next, nitrogen-free oxide hard mask layer 44 is formed over low K dielectric layer 42 (step 29 and FIG. 3B). Nitrogen-free oxide hard mask layer 44 in accordance with an embodiment of the present invention is a silicon oxide layer having a nitrogen density of about 1×10¹⁶ atoms/cm³ or less.

The thickness of the hard mask layer 44 varies depending on the application the layers are used for. In one embodiment the overall thickness of layer 44 is between about 500-5000 Å, depending on the thickness of the low K dielectric layer 42 to be etched, and the selectivity between hard mask layer 44 and low K dielectric layer 42 of the chemistry utilized to etch the low K dielectric layer.

In one embodiment, hard mask 44 is deposited using a plasma enhanced CVD process in a 300 mm Producer PECVD chamber manufactured by Applied Materials, using the exemplary parameters set forth in TABLE 1 below. In certain embodiments, both high and low frequency RF power may be used to form the plasma to deposit a nitrogen-free oxide hard mask film.

TABLE 1
EXEMPLARY CONDITIONS FOR DEPOSITION
OF N-FREE HARD MASK

| Deposition Parameter | Exemplary Value |
|---|---|
| SiH₄ flow (sccm) | 350 |
| CO₂ flow (sccm) | 9000 |
| He flow (sccm) | 3500 |
| Temperature (° C.) | 350 |
| Pressure (Torr) | 5.5 |
| Spacing (mils) | 550 |
| RF Power (W @ 13.56 MHz) | 300 |

The specific gas flow rates and other film deposition parameters discussed above are optimized for deposition processes run in a PRODUCER® PECVD chamber manufactured by Applied Materials and outfitted for 300 mm wafers. A person of ordinary skill in the art will recognize that the rates at which various precursor gases in the process gas are introduced are chamber specific and will vary if chambers of other designs and/or volumes are employed.

Referring now to FIG. 3C, a photoresist layer 48 is next formed over nitrogen-free oxide hard mask 44 (step 31). As shown in FIG. 3D (step 32), photoresist layer 48 is then exposed to radiation 47 transmitted through reticle 49. Specifically, reticle 49 includes opaque portions 49a which block the incident radiation 47, and also includes transparent portions 49b which transmit the incident radiation 47. Due to the presence of reticle 49, selective regions of photoresist layer 48 are exposed to radiation for patterning according to a via pattern. Specifically, regions 48a of photoresist layer 48 are exposed to radiation, while regions 48b remain unaffected. As a result of this radiation exposure, photoresist in regions 48a may experience a change, for example the generation of acidic species.

In one embodiment, photoresist layer 48 is exposed to deep UV radiation having a wavelength of about 243, 198 or 157 nm. In another embodiment, layer 48 is exposed to e-beam radiation. Since this example shows formation of a via for an interconnect metallization layer, layer 48 is patterned in step 32 using a via pattern 50. It is to be understood, however, that any desired pattern could be transferred into layer 48 and then subsequently transferred into the underlying layers.

As shown in FIG. 3E (step 33), developer solution is next applied to the processed substrate. Photoresist material in regions 48a exposed to the radiation is soluble in the developer solution; photoresist material in regions 48b not exposed to the radiation is insoluble in the developer solution. FIG. 3E thus shows removal of photoresist 48 in exposed regions 48a, but not in unexposed regions 48b, to form via pattern 50.

Next, the via pattern is then transferred into the film stack beneath the photoresist material to form via hole 54; Specifically, pattern 50 is first transferred into the underlying oxide hard mask 44 utilizing an etching chemistry that selectively etches the nitrogen-free oxide layer relative to the photoresist. (step 34 and FIG. 3F)

After transferring via pattern 50 into the nitrogen-free oxide hard mask 44, remaining photoresist layer may be stripped using an appropriate ashing process (step 35 and FIG. 3G) as is known to those of skill in the art.

The via pattern is then transferred into portions of the low K dielectric layer 42 exposed by removal of the oxide hard mask 44 (step 36 and FIG. 3H). This step creating via hole 54 in low K dielectric layer 42 may be accomplished utilizing an etching chemistry that selectively etches the low K dielectric material relative to the nitrogen-free oxide hard mask. At the conclusion of step 36 and FIG. 3H, the hard mask may be removed, leaving the via hole ready to receive a conductive material such as copper, thereby establishing an electrical connection through the low K dielectric layer.

Transfer of the pattern of photoresist into the underlying film stack comprising the oxide hard mask and the low K dielectric can be accomplished using any appropriate etching technique or combination of etching techniques, such as exposing the substrate to a plasma of reactive fluorine species. The precise chemistry and conditions of the etching steps employed, depend on the material of the layers being etched as is known to those of skill in the art. Typically, an etch chemistry is selected that removes material exposed that is desired to be etched (e.g., the low K dielectric material and/or the nitrogen-free oxide in the via location) at a significantly faster rate than it removes material exposed to the plasma that is not intended to be etched (e.g., portions of the photoresist and/or hard mask lying outside the via region).

The process for patterning low K dielectric material illustrated in connection with FIGS. 3A-H offers a number of benefits. One important benefit is the avoidance of poisoning of the photoresist material during the patterning process. Specifically, subsequent to the resist exposure step shown in FIG. 3D, the presence of the underlying nitrogen-free oxide hard mask blocks diffusion of nitrogen into the resist. The barrier offered by the hard mask thus prevents unwanted neutralization of the acidic species generated during radiation exposure, thereby ensuring complete and accurate development of the resist material. Complete development of the resist in turn ensures that the patterned resist will be faithfully and accurately transferred to the underlying low K dielectric material.

It is to be understood that the example of FIGS. 2 and 3A-H is for exemplary purposes only, and the present application is not restricted to this particular application. For example, the sequence of steps described and illustrated in FIGS. 3A-H show the exposure and development of positive photoresist to pattern the low K dielectric. However, this is not required by the present invention, and in alternative embodiments, nitrogen-free oxide hard mask could also be employed with negative photoresist to pattern low K dielectric material.

And while the embodiment of FIGS. 3A-H show the stripping of photoresist after transfer of the via pattern into the nitrogen-free oxide hard mask, this particular order of steps is not required by the present invention. In certain alternative embodiments, photoresist layer 48 may be stripped after the via pattern is transferred through hard mask layer 44 into low K dielectric layer 42.

And while the example of FIGS. 3A-H shows formation of a nitrogen-free hard mask material from silicon-and-oxygen-containing precursor gases of silane and carbon dioxide, respectively, the present invention is not limited to the use of these particular gases to form the hard mask. Embodiments of nitrogen-free oxide hard masks can be formed from any combination of nitrogen-free precursor gases, including but not limited to oxygen sources such as O₂, CO, O₃, H₂O vapor, and silicon sources including but not limited to SiₓH₂ₓ₊₂, SiₓCl₂ₓ₊₂, (CH₃)ₓSiH_{y}, or combinations thereof, with x=1-4 and y=4-x: i.e. SiH₄, Si₂H₆, Si₃H₈, SiH₂Cl₂, SiCl₄, Si₂Cl₆, methylsilane, dimethylsilane, trimethylsilane, tetramethylsilane, and combinations thereof, and also SiI₄, SiF₄, and TEOS.

Moreover, layers of material in addition to those shown in FIGS. 3A-H may be present during formation of a via in an interconnect structure. As discussed in detail below in connection with an embodiment showing fabrication of a dual damascene structure, certain photolithographic processes may employ an anti-reflective coating (ARC) layer beneath the photoresist in order to facilitate irradiation with a precise depth of field.

Thus while the example of FIGS. 3A-H shows a nitrogen-free hard mask according to an embodiment of the present invention as being employed to create a via in an interconnect structure, the present invention is not limited to this particular application. Alternative embodiments in accordance with the present invention can be used to form a variety of other types of structures in dielectric layers or dielectric stacks. For example, a nitrogen-free oxide hard mask in accordance with an embodiment of the present invention may be utilized to form a dual damascene structure.

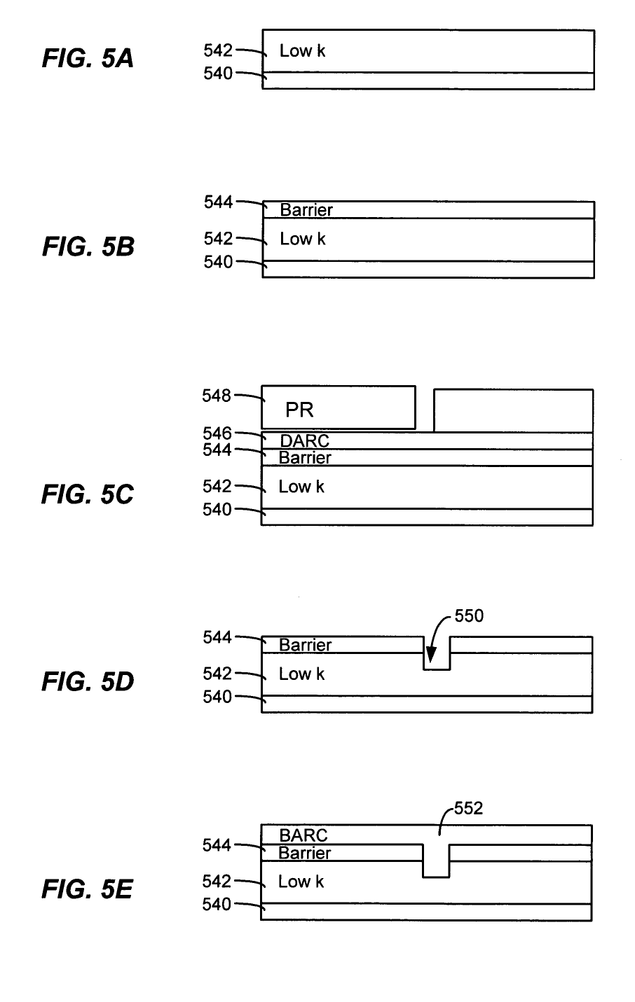

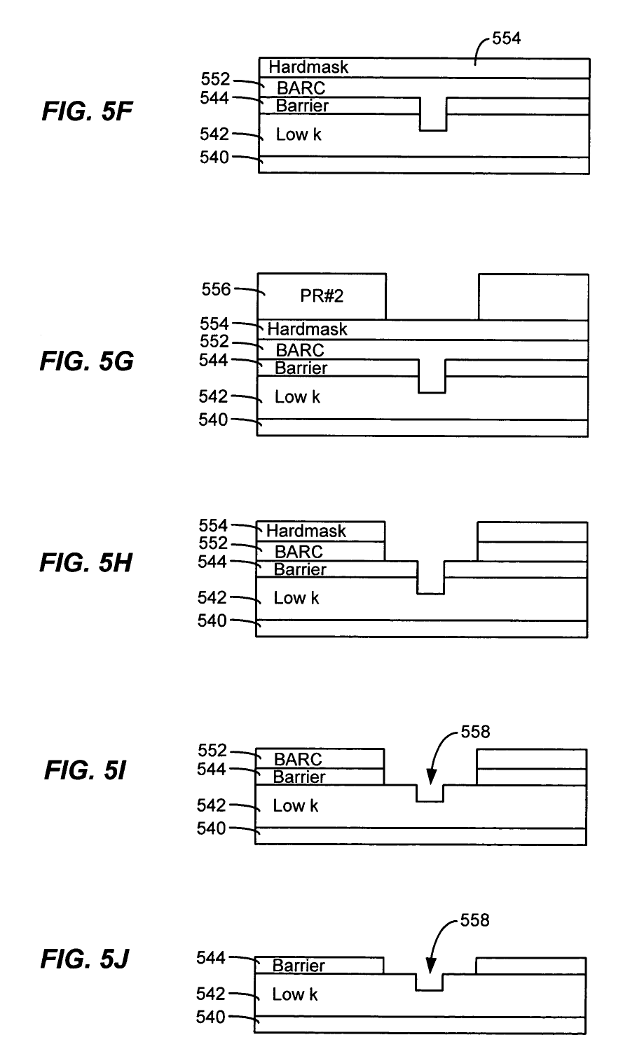

FIGS. 5A-J show simplified cross-sectional views of steps of forming a via-first dual damascene structure in accordance with such an embodiment of the present invention. FIG. 5A shows formation of a nitrogen-containing low K dielectric layer 542 over substrate 540. Next, in FIG. 5B, a barrier material 544 such as BLOK® is formed over low K dielectric layer 542. Barrier material 544 functions to block the unwanted diffusion of metal ions (Cu in particular) from overlying metallization layers into the underlying low K dielectric layer.

Referring now to FIG. 5C, a dielectric anti-reflective coating (DARC®) 546 is uniformly deposited over barrier layer 544. A via pattern is then formed in first photoresist layer 548 developed over DARC®, by selective radiation exposure transmitted through a reticle, as explained above in connection with FIGS. 3D-E.

Next, as shown in FIG. 5D the via pattern is transferred through DARC 546 and barrier layer 544 part way into the underlying low k dielectric layer 542 to create partial via hole 550. The remaining photoresist and DARC are then removed.

As shown in FIG. 5E, a bottom anti-reflective coating (BARC) material 552 is then spun on over the surface of the processed wafer, penetrating into partial via hole 550. The spun on BARC 552 is then cured.

In expectation of patterning a second layer of photoresist to form the trench component of the dual damascene structure, FIG. 5F shows formation of nitrogen-free hard mask layer 554 on top of BARC layer 552. Nitrogen-free hard mask layer 554 in accordance with an embodiment of the present invention serves to block any possible diffusion of nitrogen from the now-exposed low K dielectric layer 542 through BARC 552 into an overlying photoresist layer.

FIG. 5G shows formation of a trench pattern in such a second photoresist layer 556 overlying nitrogen-free hard mask 554, by selective exposure to radiation transmitted through a reticle followed by development.

FIG. 5H shows transfer of the trench pattern through nitrogen-free hard mask 554 and underlying BARC layer 552. This step also results in the removal of BARC material within the partial via hole 550 due to selectivity of the etching chemistry to BARC relative to the low K dielectric material. The second photoresist material is then removed.

FIG. 5I shows transfer of the trench pattern into portions of the low K layer 542 exposed during the prior step. As a result of this etching step, the trench-via dual damascene structure 558 is formed in the low K dielectric material 542. The hard mask layer is then removed by selective etching.

FIG. 5J shows removal of the overlying BARC layer to reveal the low K dielectric layer exhibiting the trench/via combination dual damascene structure 558. This dual damascene feature is ready to receive a conductive material such as copper, to establish an electrically conducting pathway through the low K dielectric layer.

While FIGS. 5A-J show use of a nitrogen-free hard mask in a via-first dual damascene process, embodiments in accordance with the present invention are not limited to this particular flow of process steps. Alternatively, a nitrogen free hard mask layer in accordance with the present invention could be utilized to block diffusion of nitrogen into a second photoresist mask used to transfer a via pattern of a trench-first dual damascene process flow.

Other potential applications for a nitrogen-free oxide hard mask in accordance with an embodiment of the present invention include but are not limited to use in preventing resist poisoning during formation of MOSFET gates and bitline structures.

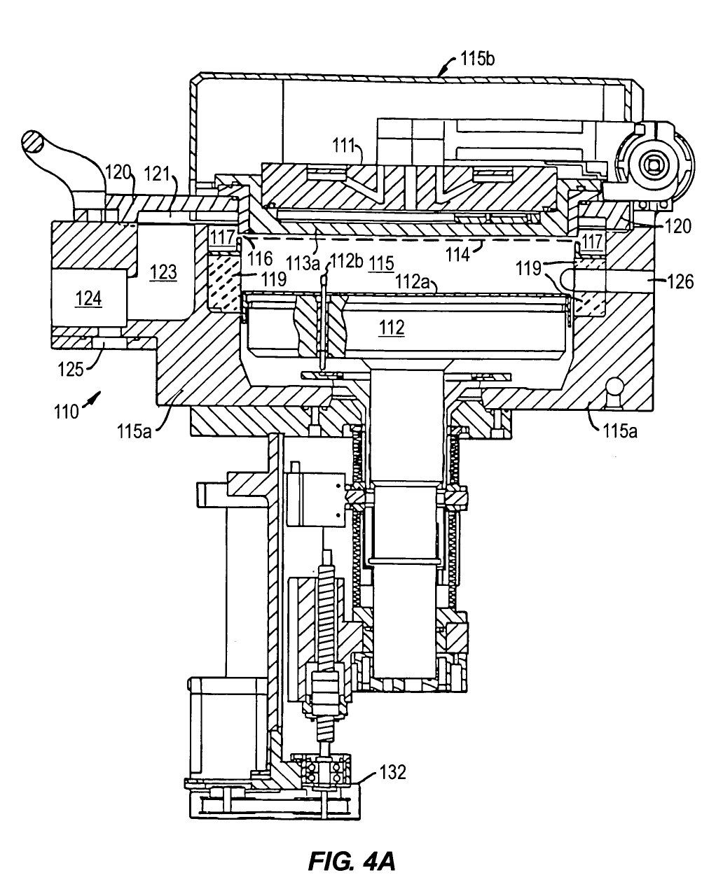

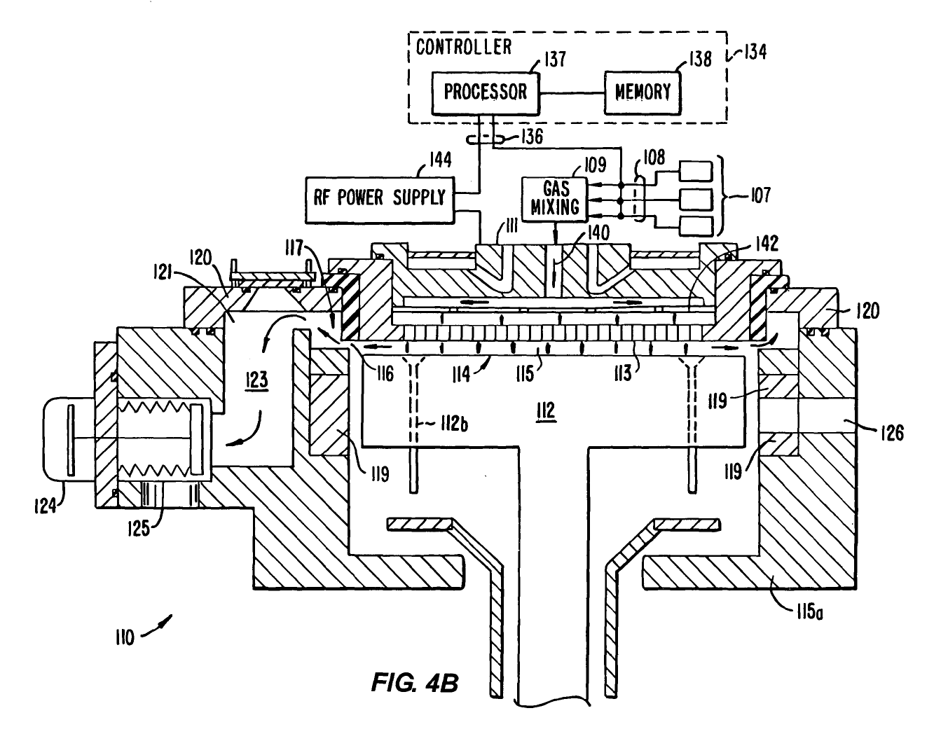

A nitrogen-free hard mask according to the present invention can be deposited in a variety of different plasma CVD chambers. An example of one suitable chamber is set forth below and discussed with respect to FIGS. 4A and 4B, which are vertical, cross-sectional views of a CVD system 110, having a vacuum or processing chamber 15 that includes a chamber wall 115a and chamber lid assembly 115b.

CVD system 110 contains a gas distribution manifold 111 for dispersing process gases to a substrate (not shown) that rests on a heated pedestal 112 centered within the process chamber. During processing, the substrate (e.g. a semiconductor wafer) is positioned on a flat (or slightly convex) surface 112a of pedestal 112. The pedestal can be moved controllably between a lower loading/off-loading position (depicted in FIG. 4A) and an upper processing position (indicated by dashed line 114 in FIG. 4A and shown in FIG. 4B), which is closely adjacent to manifold 111. A centerboard (not shown) includes sensors for providing information on the position of the wafers.

Deposition and carrier gases are introduced into chamber 115 through perforated holes of a conventional flat, circular gas distribution or faceplate 113a. More specifically, deposition process gases flow into the chamber through the inlet manifold 111 (indicated by arrow 140 in FIG. 4B), through a conventional perforated blocker plate 142 and then through holes 113b in gas distribution faceplate 1113a.

Before reaching the manifold, deposition and carrier gases are input from gas sources 107 through gas supply lines 108 (FIG. 4B) into a mixing system 109 where they are combined and then sent to manifold 111. Generally, the supply line for each process gas includes (i) several safety shut-off valves (not shown) that can be used to automatically or manually shut-off the flow of process gas into the chamber, and (ii) mass flow controllers (also not shown) that measure the flow of gas through the supply line. When toxic gases are used in the process, the several safety shut-off valves are positioned on each gas supply line in conventional configurations.

The deposition process performed in CVD system 110 can be either a thermal process or a plasma-enhanced process. In a plasma-enhanced process, an RF power supply 144 applies electrical power between the gas distribution faceplate 113a and the pedestal so as to excite the process gas mixture to form a plasma within the cylindrical region between the faceplate 113a and the pedestal. (This region will be referred to herein as the “reaction region”). Constituents of the plasma react to deposit a desired film on the surface of the semiconductor wafer supported on pedestal 112. RF power supply 144 is a mixed frequency RF power supply that typically supplies power at a high RF frequency (RF1) of 13.56 MHz and at a low RF frequency (RF2) of 360 KHz to enhance the decomposition of reactive species introduced into the vacuum chamber 115.

In a thermal process, RF power supply 144 would not be utilized. Instead, voltage would be applied to cause resistive heating of a heater element present on the surface of the pedestal 112. The heater element would be in physical contact with and cause heating of the semiconductor wafer. The process gas mixture would in turn thermally react to deposit the desired film on the surface of the semiconductor wafer. The extent of heating, and hence the amount of thermal energy imparted to the deposition reaction, can be controlled to obtain deposited films having the desired characteristics. In the particular process described above, the temperature of the heater is controlled to be about 350° C., but can be higher or lower depending upon the particular process.

During a plasma-enhanced deposition process, the plasma heats the entire process chamber 110, including the walls of the chamber body 115a surrounding the exhaust passageway 123 and the shut-off valve 124. When the plasma is not turned on or during a thermal deposition process, a hot liquid is circulated through the walls 115a of the process chamber to maintain the chamber at an elevated temperature. A portion of these heat exchanging passages 118 in the lid of chamber 110 is shown in FIG. 4B. The passages in the remainder of chamber walls 115a are not shown. Fluids used to heat the chamber walls 115a include the typical fluid types, i.e., water-based ethylene glycol or oil-based thermal transfer fluids. This heating (referred to as heating by the “heat exchanger”) beneficially reduces or eliminates condensation of undesirable reactant products and improves the elimination of volatile products of the process gases and other contaminants that might contaminate the process if they were to condense on the walls of cool vacuum passages and migrate back into the processing chamber during periods of no gas flow.

The remainder of the gas mixture that is not deposited in a layer, including reaction byproducts, is evacuated from the chamber by a vacuum pump (not shown). Specifically, the gases are exhausted through an annular, slot-shaped orifice 116 surrounding the reaction region and into an annular exhaust plenum 117. The annular slot 116 and the plenum 117 are defined by the gap between the top of the chamber's cylindrical side wall 115a (including the upper dielectric lining 119 on the wall) and the bottom of the circular chamber lid 120. The 360° circular symmetry and uniformity of the slot orifice 116 and the plenum 117 help achieve a uniform flow of process gases over the wafer so as to deposit a uniform film on the wafer.

From the exhaust plenum 117, the gases flow underneath a lateral extension portion 121 of the exhaust plenum 117, past a viewing port (not shown), through a downward-extending gas passage 123, past a vacuum shut-off valve 124 (whose body is integrated with the lower chamber wall 115a), and into the exhaust outlet 125 that connects to the external vacuum pump (not shown) through a foreline (also not shown).

The wafer support platter of the pedestal 112 (preferably aluminum, ceramic, or a combination thereof) is resistively-heated using an embedded single-loop embedded heater element configured to make two full turns in the form of parallel concentric circles. An outer portion of the heater element runs adjacent to a perimeter of the support platter, while an inner portion runs on the path of a concentric circle having a smaller radius. The wiring to the heater element passes through the stem of the pedestal 112.

Typically, any or all of the chamber lining, gas inlet manifold faceplate, and various other reactor hardware are made out of material such as aluminum, anodized aluminum, or ceramic. An example of such a CVD apparatus is described in U.S. Pat. No. 5,558,717 entitled “CVD Processing Chamber,” issued to Zhao et al. The U.S. Pat. No. 5,558,717 is assigned to Applied Materials, Inc., the assignee of the present invention, and is hereby incorporated by reference in its entirety.

A lift mechanism and motor 132 (FIG. 4A) raises and lowers the heater pedestal assembly 112 and its wafer lift pins 112b as wafers are transferred into and out of the body of the chamber by a robot blade (not shown) through an insertion/removal opening 126 in the side of the chamber 110. The motor 132 raises and lowers pedestal 112 between a processing position 114 and a lower, wafer-loading position. The motor, valves or flow controllers connected to the supply lines 108, gas delivery system, throttle valve, RF power supply 144, and chamber and substrate heating systems are all controlled by a system controller 134 (FIG. 4B) over control lines 136, of which only some are shown. Controller 134 relies on feedback from optical sensors to determine the position of movable mechanical assemblies such as the throttle valve and susceptor which are moved by appropriate motors under the control of controller 134.

System controller 134 controls all of the activities of the CVD machine. The system controller executes system control software, which is a computer program stored in a computer-readable medium such as a memory 138. Preferably, memory 138 is a hard disk drive, but memory 138 may also be other kinds of memory. The computer program includes sets of instructions that dictate the timing, mixture of gases, chamber pressure, chamber temperature, RF power levels, susceptor position, and other parameters of a particular process. Other computer programs stored on other memory devices including, for example, a floppy disk or other another appropriate drive, may also be used to operate controller 134.

The above reactor description is mainly for illustrative purposes, and other types of plasma CVD equipment may be employed to form the ARC. Additionally, variations of the above-described system, such as variations in pedestal design, heater design, RF power frequencies, location of RF power connections and others are possible. For example, the wafer could be supported by a susceptor and heated by quartz lamps. The layer and method for forming such a layer of the present invention is not limited to any specific apparatus or specific plasma excitation method.

Having fully described several embodiments of the present invention, many other equivalents or alternative embodiments of the invention will be apparent to those skilled in the art. The above description is thus illustrative and not restrictive, and equivalents and/or alternatives are intended to be included within the scope of the present invention.

What is claimed is:

1. A method for fabricating an integrated circuit, the method comprising:
forming a low K dielectric material overlying a substrate;
forming a silicon oxide hard mask over the low K dielectric material, said silicon oxide hard mask having a density of nitrogen less than or equal to about 1×10¹⁶ atoms/cm³;
forming a layer of resist overlying the silicon oxide hard mask; and
patterning said resist layer.

2. The method of claim 1 wherein:
forming the layer of resist comprises forming a layer of photoresist; and
patterning the resist layer comprises,
irradiating the photoresist layer with deep UV radiation through a reticle, and
providing a developer solution to dissolve a portion of the photoresist layer and thereby produce the pattern.

3. The method of claim 2 wherein the photoresist layer comprises a positive photoresist, the method further comprising providing the developer solution to dissolve a portion of the positive photoresist layer exposed to the deep UV radiation through the reticle.

4. The method of fabricating an integrated circuit according to claim 1 further comprising transferring the pattern formed in the resist layer to the low K dielectric layer.

5. The method of claim 4 further comprising the step of stripping the resist after the pattern has been transferred to the hard mask.

6. The method of claim 5 wherein stripping of the resist occurs before the pattern has been transferred to the low K dielectric.

7. The method of claim 6 wherein forming the low K dielectric layer comprises forming a low K dielectric layer selected from the group consisting of an SiC, an SiOC or a spin-on dielectric material having a dielectric constant of 3.5 or less.

8. The method of claim 1 wherein forming the hard mask layer comprises causing reaction between a nitrogen-free silicon source and a nitrogen-free oxygen source to deposit the silicon oxide.

9. The method of claim 8 wherein:
the nitrogen-free silicon source is selected from the group consisting of monosilane, TEOS, Si₂H₆, Si₃H₈, and SiF₄; and
the nitrogen-free oxygen source is selected from the group consisting of ozone, steam, oxygen, and carbon dioxide.

10. The method of claim 8 wherein forming the hard mask layer comprises heating a wafer to about 350° C. in the presence of a plasma and the nitrogen-free silicon source and the nitrogen free oxide source.

11. The method of claim 1 wherein forming the hard mask layer comprises forming an oxide layer having a thickness of between about 500 and 5000 Å.

12. The method of claim 1 wherein forming the low K dielectric over the substrate comprises forming the low K dielectric over at least one of an interconnect metallization layer and a metal diffusion barrier material.

13. The method of claim 1 further comprising forming an anti-reflective coating over the low K dielectric material, wherein the hard mask layer is formed over the anti-reflective coating.

14. A method of forming a dual damascene structure comprising the steps of:
patterning a first resist overlying a low K dielectric layer to reveal a first exposed region having a first width;
removing a portion of the low K dielectric layer underlying the first exposed region to form a recess;
removing the first resist;
forming a material over the low K dielectric material and within the recess;
forming an oxide hard mask having a nitrogen density of less than about 1×10¹⁶ atoms/cm³ over the material;
patterning a second resist over the oxide hard mask to reveal a second exposed region;
removing the oxide hard mask underlying the second exposed region to form an opening having a second width over the filled recess;
removing the second resist;
removing the material underlying the opening selective to the low K dielectric layer;
removing the low K dielectric underlying the opening to create a dual damascene hole; and
forming a conductor material within the dual damascene hole.

15 The method of claim 14 wherein the first width is greater than the second width, such that the recess comprises a trench.

16. The method of claim 15 further comprising removing the hard mask and the material prior to forming the conductor.

17. The method of claim 14 wherein the first width is less than the second width, such that the recess comprises a via hole.

18. The method of claim 14 wherein the material comprises an anti-reflective coating.

19. The method of claim 14 wherein the low K dielectric layer is selected from the group consisting of an SiC, an SiOC or a spin-on dielectric material having a dielectric constant of 3.5 or less.

20. The method of claim 14 wherein forming the oxide hard mask layer comprises causing reaction between a nitrogen-free silicon source and a nitrogen-free oxygen source to deposit silicon oxide.

21. A method of preventing resist poisoning comprising:
forming an oxide hard mask having a nitrogen density of less than about 1×10¹⁶ atoms/Cm³ between a low K dielectric layer and a resist layer to inhibit diffusion of nitrogen into the resist layer.

22. A hard mask layer for blocking diffusion of nitrogen into an overlying resist layer, the hard mask layer comprising silicon oxide having a density of nitrogen less than or equal to about 1×10¹⁶ atoms/cm³.
